(19) United States
(12) Patent Application Publication
(10) Pub. No.: US 2003/0153101 A1
(43) Pub. Date: Aug. 14, 2003

(54) Method for surface treatment and system for fabricating semiconductor device

(76) Inventors: Michihiko Takase, Nara (JP); Akihisa Yoshida, Kyoto (JP); Bunji Mizuno, Nara (JP)

Correspondence Address: Andrew L Ney, Ratner & Prestia, One Westlakes Berwyn Suite 301, PO Box 980, Valley Forge, PA, 19482-0980, US

(21) Appl. No.: 10/297,361

(22) PCT Filed: Mar. 25, 2002
(86) PCT No.: PCT/JP02/02863

(30) Foreign Application Priority Data
Apr. 9, 2001 (JP) 2001-109598

(51) Int. Cl. H01L 21/00; H01L 21/04; B05C 11/00

(52) U.S. Cl. 438/7; 438/510; 118/712

(57) ABSTRACT

A surface treatment method includes: a plasma conversion step of using plasma to convert a substance into the form of plasma, thereby generating a first plasma substance and a second plasma substance; a step of beginning introduction of the first plasma substance, which is generated by using the plasma, into a substratum; a step of ending introduction of the first plasma substance into the substratum; a step of observing the state of the second plasma substance, which is generated by using the plasma, prior to the ending step; and a step of controlling a plasma process time, which represents a time interval from the beginning step to the ending step, based on the observation result obtained at the observation step, such that a total dosage of the first plasma substance, which represents a total quantity of the first plasma substance introduced into the substratum, becomes equal to a desired total dosage.

### TECHNICAL FIELD

The present invention relates to a surface treatment method and a production method of a semiconductor device, wherein a plasma substance, which is an atom, a molecule, a compound, an alloy, or the like, in the state of plasma, is introduced into a substratum, such as a semiconductor substrate or the like.

### BACKGROUND ART

In order to produce a semiconductor device, it is necessary to provide a step of introducing a small amount of impurity, such as phosphor, boron, etc., into a semiconductor substrate so as to produce n-type and p-type semiconductors.

As a method for introducing such impurity into a semicondutor substrate, an ion implantation method is widely employed. Since a junction depth of a semiconductor device decreases as the size of the semiconductor device decreases, a reduction in the energy of implanted ion is demanded in an ion implantation process. In the above described ion implantation method, an inherent problem exists, i.e., a throughput is low in a low energy region where the energy of implanted ion is low.

In order to address such a problem, various impurity introduction methods which can substitute for the above ion implantation method have been proposed. Among such methods, active research is being carried out on plasma doping, in which plasma impurity, i.e., impurity in the form of plasma, is introduced into a substratum, such as a semiconductor substrate or the like. The reasons for that are described below. Plasma doping is a room-temperature process which can be carried out at room temperature. Plasma doping is interchangeable with a conventional ion implantation method. Plasma doping can maintain a high throughput in a low energy region. Further, a plasma doping apparatus is less expensive than an ion implantation apparatus. Furthermore, the plasma doping apparatus is smaller than the ion implantation apparatus, and therefore consumes a smaller area in a semiconductor production system.

When introducing plasma impurity into a semiconductor substrate by plasma doping, before mass-production of the plasma impurity to be introduced into the semiconductor substrate is started, the plasma impurity is preliminarily introduced to the semiconductor substrate. The dosage of the plasma impurity, which represents the quantity of the plasma impurity introduced into the semiconductor substrate, is calculated by secondary ion mass spectrometry (SIMS) in order to detect an increase or decrease in the dosage of the plasma impurity. Then, a doping time (plasma process time), which represents a time interval from a time when introduction of the plasma impurity into the semiconductor substrate is begun to a time when introduction of the plasma impurity into the semiconductor substrate is ended, is adjusted based on the calculated dosage. Thereafter, based on the adjusted doping time, the mass-production of the plasma impurity is begun.

However, in such conventional plasma doping, the dosage of the plasma impurity, which represents the quantity of the plasma impurity introduced into the semiconductor substrate, is varied because of a variation in the state of plasma which is used to convert the impurity into the form of plasma. Accordingly, in the semiconductor device produced by utilizing plasma doping, the electrical resistance values of a source region, a drain region, and a gate electrode are not uniform. As a result, the device driving power of a semiconductor device produced by utilizing plasma doping results in defective, non-uniform power, and the yield of such a semiconductor device decreases.

There is a method that addresses such a problem, wherein a variation in the state of plasma, which is used to convert the impurity into the form of plasma, is observed, and the variation in the state of plasma is controlled by adjusting a plurality of parameters for generating plasma based on the observed variation in the state of plasma. However, if one of the plurality of parameters for generating plasma is changed, the other parameters are changed accordingly. The plasma which is used to convert the impurity into the form of plasma cannot sufficiently follow a change in a parameter for generating the plasma. Thus, it is extremely difficult to control a variation in the state of plasma by adjusting the parameters for generating the plasma.

Although the yield of the semiconductor device can be improved somewhat by preliminarily introducing the plasma impurity to the semiconductor substrate before the beginning of the mass-production of plasma impurity, analyzing the dosage of the plasma impurity calculated by SIMS, and adjusting the doping time (plasma process time) based on the dosage analysis result calculated by SIMS, a considerable time is required for analyzing the dosage calculated by SIMS, and accordingly, the production time of the semiconductor device becomes long.

The present invention was conceived in order to solve such a problem. An objective of the present invention is to provide a surface treatment method and a production apparatus of a semiconductor device which can reduce the production time.

Another objective of the present invention is to provide a surface treatment method and a production apparatus of a semiconductor device which can improve the yield.

### DISCLOSURE OF THE INVENTION

A surface treatment method according to the present invention includes: a plasma conversion step of using plasma to convert a substance into the form of plasma, thereby generating a first plasma substance and a second plasma substance; a step of beginning introduction of the first plasma substance, which is generated by using the plasma, into a substratum; a step of ending introduction of the first plasma substance into the substratum; a step of observing the state of the second plasma substance, which is generated by using the plasma, prior to the ending step; and a step of controlling a plasma process time, which represents a time interval from the beginning step to the ending step, based on the observation result obtained at the observation step, such that a total dosage of the first plasma substance, which represents a total quantity of the first plasma substance introduced into the substratum, becomes equal to a desired total dosage, whereby the above objective is achieved.

The observation step may be performed after the beginning step. The observation step may observe an emission intensity of the second plasma substance generated by using the plasma. The controlling step may obtain, based on the emission intensity observed at the observation step, a relationship between the plasma process time and a dosage of the first plasma substance, which represents a quantity of the first plasma substance introduced into the substratum, and control a timing at which the ending step is performed according to the relationship between the plasma processing time and the dosage of the first plasma substance.

The observation step may be performed prior to the beginning step.

The second plasma substance generated at the plasma conversion step may contain ions or radicals. The observation step may observe the state of one of the ion and the radical using one of emission spectrometry and laser-induced fluorescence spectroscopy.

The second plasma substance generated at the plasma conversion step may contain ions. The observation step may observe the state of the ions using one of an E×B filter and quadrupole mass spectrometry (QMAS).

The plasma conversion step may convert the substance into the form of plasma in a chamber, thereby generating the first plasma substance and the second plasma substance. The observation step may observe the state of the second plasma substance from outside of the chamber.

The plasma conversion step may convert the substance into the form of plasma in a chamber, thereby generating the first plasma substance and the second plasma substance. The observation step may observe the state of the second plasma substance from inside the chamber.

The substratum may be a semiconductor substrate. The substance may be an impurity.

The first plasma substance may be boron.

The second plasma substance may contain BH radicals.

A production apparatus of a semiconductor device according to the present invention includes: holding means for holding a semiconductor substrate in a chamber; source gas supply means for supplying a source gas including an impurity into the chamber; a plasma source for generating plasma used for converting the impurity, which is included in the source gas supplied by the source gas supply means, into the form of plasma, thereby generating a first plasma impurity and a second plasma impurity in the chamber; introduction means for introducing the first plasma impurity into the semiconductor substrate; observation means for observing the state of the second plasma impurity which is generated using the plasma; control means for controlling a plasma process time, which represents a time interval from a time when introduction of the first plasma impurity into the semiconductor substrate is begun to a time when introduction of the first plasma impurity into the semiconductor substrate is ended, based on the observation result obtained by the observation means, such that a total dosage of the first plasma impurity, which represents a total quantity of the first plasma impurity introduced into the substratum, becomes equal to a desired total dosage, whereby the above objective is achieved.

A surface treatment method according to the present invention includes: a plasma conversion step of using plasma to convert a substance into the form of plasma, thereby generating a first plasma substance and a second plasma substance; a step of beginning introduction of the first plasma substance, which is generated by using the plasma, into a substratum; a step of observing the state of the second plasma substance which is generated by using the plasma; a step of obtaining a dose rate of the first plasma substance introduced into the substratum, based on the observation result at the observation step, a step of obtaining a total dosage of the first plasma substance, which represents the total quantity of the first plasma substance introduced into the substratum, based on the dose rate obtained at the dose rate obtaining step; and a step of ending introduction of the first plasma substance into the substratum, based on the total dosage obtained at the total dosage obtaining step and a predetermined desired total dosage, whereby the above objective is achieved.

### BRIEF DESCRIPTION OF THE DRAWINGS

FIG. 1 shows a structure of a MOS transistor production apparatus according to an embodiment of the present invention.

FIG. 2 is a cross-sectional view illustrating a MOS transistor formed by a MOS transistor production apparatus according to an embodiment of the present invention.

FIG. 3 is a cross-sectional view illustrating a MOS transistor formed by a MOS transist or production apparatus according to an embodiment of the present invention.

FIG. 4 is a graph showing the relationship between the emission intensity of BH radical and the RF power and the sheet resistance according to an embodiment of the present invention.

FIG. 5 is a graph showing the result of measurement where the concentration distribution of boron was measured along the depth direction of a semiconductor substrate by secondary ion mass spectrometry (SIMS) according to an embodiment of the present invention.

FIG. 6 is a graph that shows the relationship between the plasma process time and the sheet resistance and the dosage of boron according to an embodiment of the present invention.

FIG. 7 is a graph showing the relationship between the plasma process time and the dosage of boron for respective emission intensities according to an embodiment of the present invention.

FIG. 8 is a flowchart illustrating a procedure of a surface treatment method according to an embodiment of the present invention.

FIG. 9 is a graph showing the relationship between the plasma process time and the dosage of boron according to an embodiment of the present invention.

FIG. 10 is a flowchart illustrating a procedure of another surface treatment method according to an embodiment of the present invention.

### BEST MODE FOR CARRYING OUT THE INVENTION

In a surface treatment method according to the present embodiment, the doping time (plasma processing time) is controlled such that the total dosage of the plasma impurity, which represents the total quantity of the plasma impurity introduced into the semiconductor substrate, becomes a desired dosage.

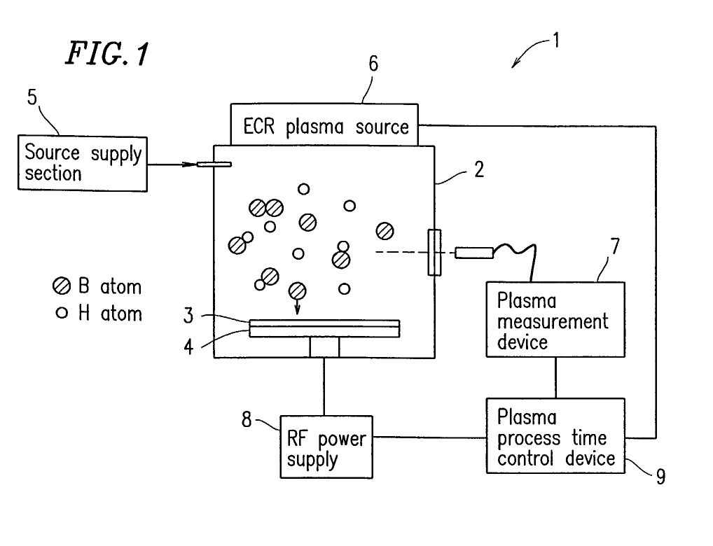

In the present embodiment, a surface treatment method, which is employed in production of a MOS transistor wherein plasma impurity is introduced into a semiconductor substrate, is described as an example. FIG. 1 shows a structure of a MOS transistor production apparatus 1 according to the present embodiment. The MOS transistor production apparatus 1 includes a chamber 2 provided for introducing plasma impurity, which is generated by converting impurity in the form of plasma, into the semiconductor substrate 3. In the chamber 2, a substrate holding table 4 is provided for holding a semiconductor substrate 3 on which a MOS transistor is to be formed.

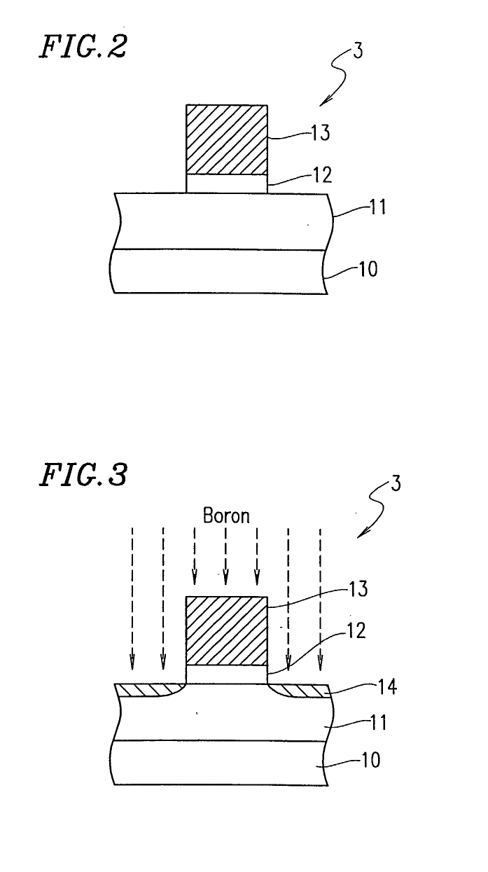

FIG. 2 is a cross-sectional view illustrating the semiconductor substrate 3 on which a MOS transistor is to be formed. The semiconductor substrate 3, on which a MOS transistor is to be formed, has a P-type silicon substrate 10. On the silicon substrate 10, an N well region 11 is formed so as to cover the P-type silicon substrate 10. Partially on the N well region 11, a gate oxide film 12 is formed by thermally growing a silicon oxide film, or the like, so as to have a thickness of about 3 nm. On the gate oxide film 12, a gate electrode 13 having a thickness of about 200 nm is formed so as to conform with the gate oxide film 12. The gate length of the gate electrode 13 is about 150 nm.

The MOS transistor production apparatus 1 includes a source supply section 5. The source supply section 5 supplies a source gas containing B₂H₆ as impurity into the chamber 2. The source supply section 5 has a container (not shown) including B₂H₆ in the form of gas and a container (not shown) including He in the form of gas which is used for diluting B₂H₆. The source supply section 5 has a mixer which includes a bulb (not shown), etc. The mixer mixes B₂H₆ and He, which are included in the containers in the form of gas, at any ratio. The mixer then adjusts the flow rate of the mixture of B₂H₆ and He, which has been mixed in the form of gas, to any flow rate by using the bulb (not shown), and supplies the adjusted gas into the chamber 2.

The MOS transistor production apparatus 1 includes an ECR plasma source 6. The ECR plasma source 6 converts B₂H₆, which is included in the source gas supplied from the source supply section 5 into the chamber 2, in the form of plasma, so as to generate, for example, ions or radicals of boron or a boron compound, such as B⁺, B₂⁺, B₂H₂⁺, or the like; ions or radicals of hydrogen, such as H⁺, H₂⁺, or the like; and BH radicals. The power of the ECR plasma source 6 is about 500 watts (W). The degree of vacuum employed when B₂H₆ is converted into plasma is about 4×10⁻⁴ Torr, where 1 Torr=133.322 pascal (Pa).

The MOS transistor production apparatus 1 includes a plasma measurement device 7. The plasma measurement device 7 is provided out of the chamber 2. The plasma measurement device 7 observes the state of plasma generated in the chamber 2 by the ECR plasma source 6, through an observation window formed in the chamber 2. Specifically, the plasma measurement device 7 measures the intensity of emission at a wavelength of 4332 Å which corresponds to a transition of (A1Π−X1Σ) of BH radicals generated by converting B₂H₆ in the chamber 2 into the form of plasma.

The MOS transistor production apparatus 1 includes an RF power supply 8. The RF power supply 8 applies RF power of, for example, 300 watts (W) to the semiconductor substrate 3, in order to introduce into the semiconductor substrate 3 held by the substrate holding table 4 boron generated by converting B₂H₆ into the form of plasma.

FIG. 3 is a cross-sectional view illustrating a method for forming a MOS transistor on the semiconductor substrate 3. When boron generated by converting B₂H₆ into the form of plasma is introduced into the semiconductor substrate 3 on which a MOS transistor is formed, boron doping regions 14 are formed in the N well region 11 at both left and right sides of the gate oxide film 12.

The MOS transistor production apparatus 1 includes a plasma process time control section 9. The plasma process time control section 9 controls the doping time (plasma process time), which represents a time interval from a time when introduction of boron into the semiconductor substrate 3 is begun to a time when introduction of boron into the semiconductor substrate 3 is ended, based on the emission intensity of BH radicals measured by the plasma measurement device 7, such that the total dosage of boron, which represents the total quantity of boron introduced into the semiconductor substrate 3, becomes a desired dosage.

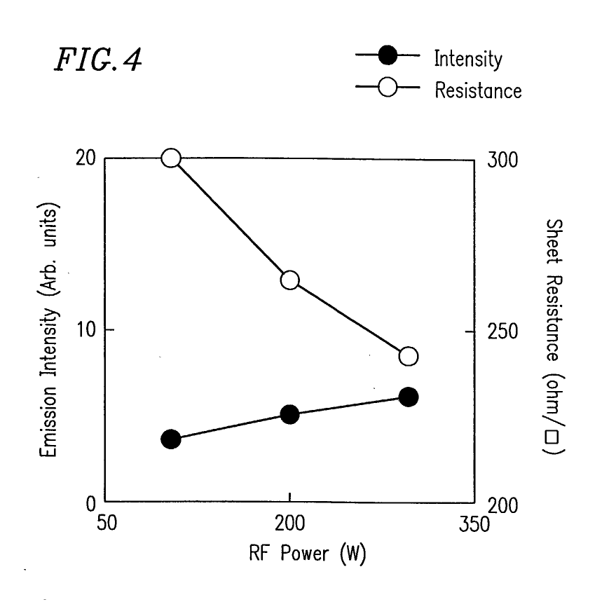

The results of experimentation carried out by the present inventors is now described in order to specify the relationship between the emission intensity of BH radicals measured by the plasma measurement device 7 and the dosage of boron which represents the quantity of boron introduced into the semiconductor substrate 3. FIG. 4 is a graph showing the relationship between the emission intensity of BH radicals and the RF power and the sheet resistance. The horizontal axis represents the RF power which is applied to the semiconductor substrate 3 from the RF power supply 8. The left vertical axis represents the emission intensity of BH radicals measured by the plasma measurement device 7. The right vertical axis represents the sheet resistance of the semiconductor substrate 3 measured after introduction of boron into the semiconductor substrate 3 is ended, and an activating thermal treatment is performed at 1000° C. for 10 seconds.

The conditions of this experimentation are as follows:

Semiconductor substrate: 6 inches, N-type silicon substrate

Doping apparatus (MOS transistor production apparatus): plasma doping apparatus (manufactured by MATSUSHITA ELECTRIC INDUSTRIAL CO., LTD.)

Doping conditions

Doping time: 100 seconds

RF power: 100 watts to 300 watts

ECR power: 500 watts

Source gas: B₂H₆ (flow rate 200 sccm)

Degree of vacuum in chamber: 1×10⁻⁴ Torr to 2×10⁻³ Torr

Activating thermal treatment: RTA, 1000° C., 10 seconds; or 1100° C., 90 minutes

Sheet resistance measurement method: four-probes-measurement

SIMS measurement

primary ion species: O²⁺

secondary ion species: Positive

primary ion energy: 3 keV

Emission analysis: the intensity of emission at a wavelength of 4332 Å, which corresponds to a transition of (A1Π−X1Σ) of BH radicals, is measured

As shown in FIG. 4, when the RF power to be applied to the semiconductor substrate 3 is increased from 100 watts to 300 watts, the intensity of emission at a wavelength of 4332 Å, which corresponds to a transition of (A1Π−X1Σ) of BH radicals, increases. When the RF power is increased from 100 watts to 300 watts, the sheet resistance of the semiconductor substrate 3, which is measured after introduction of boron into the semiconductor substrate 3 is ended, and an activating thermal treatment is performed, decreases. The decrease in the sheet resistance of the semiconductor substrate 3 means that the dosage of boron, which represents the quantity of boron introduced into the semiconductor substrate 3, increases. Thus, the experimentation result shown in FIG. 4 means that the emission intensity of BH radical increases as the dosage of boron introduced into the semiconductor substrate 3 increases.

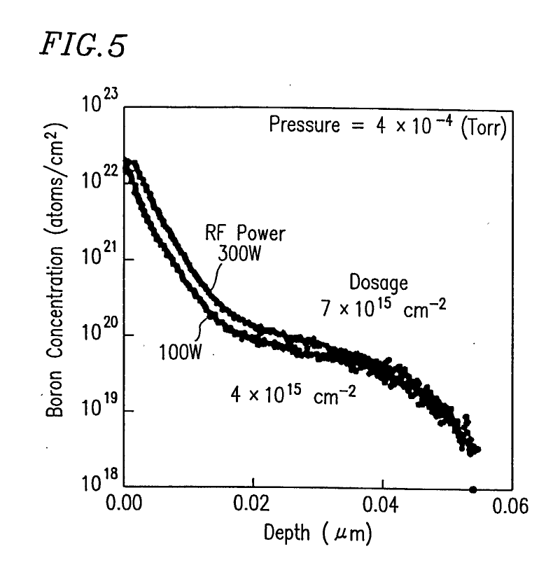

FIG. 5 is a graph showing the result of measurement where the concentration distribution of boron was measured along the depth direction of the semiconductor substrate 3 by secondary ion mass spectrometry (SIMS). The experimentation conditions are the same as those described above. The horizontal axis represents the depth in the semiconductor substrate 3 to which boron is introduced. The vertical axis represents the concentration of boron introduced into the semiconductor substrate 3. When the RF power of 100 watts was applied to the semiconductor substrate 3 in order to introduce boron into the semiconductor substrate 3, the dosage of boron introduced into the semiconductor substrate 3 was 4×10¹⁵ cm⁻². When the RF power was 300 watts, the dosage of boron was 7×10¹⁵ cm⁻², which is greater than that obtained when the RF power was 100 watts. Thus, the dosage of boron introduced into the semiconductor substrate 3 increases as the RF power applied to the semiconductor substrate 3 increases. As described above with reference to FIG. 4, the emission intensity of BH radicals increase as the RF power applied to the semiconductor substrate 3 increases. Thus, the relationship between the dosage of boron and the emission intensity of BH radical, such that the emission intensity of BH radicals increase as the dosage of boron introduced into the semiconductor substrate 3 inceases, is confirmed from the experimentation result shown in FIG. 5.

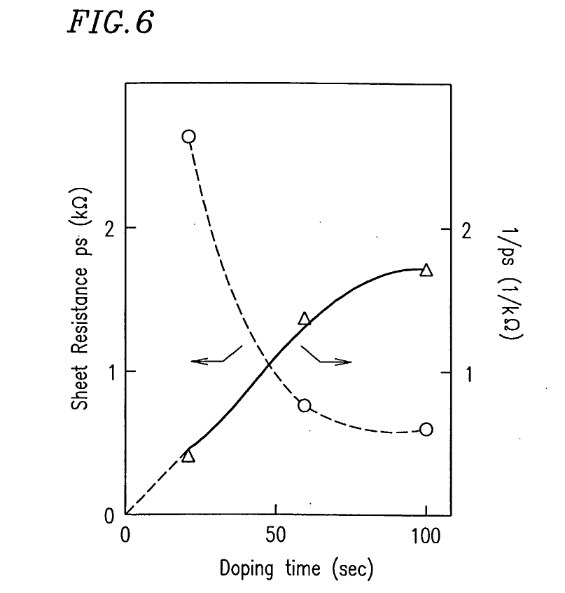

FIG. 6 is a graph that shows the relationship between the plasma process time and the sheet resistance and the dosage of boron. The experimentation conditions are the same as those described above, except that the doping time is variable. The horizontal axis represents the doping time (plasma process time), which is a time interval from a time when introduction of boron into the semiconductor substrate 3 is begun to a time when introduction of boron into the semiconductor substrate 3 is ended. The left vertical axis represents the sheet resistance of the semiconductor substrate 3 measured after introduction of boron into the semiconductor substrate 3 is ended, and an activating thermal treatment is performed at 1100° C. for 90 minutes. The right vertical axis represents the dosage of boron, which represents the quantity of boron introduced into the semiconductor substrate 3. As shown in FIG. 6, the sheet resistance of the semiconductor substrate 3 decreases as the doping time (plasma process time) increases. The dosage of boron introduced into the semiconductor substrate 3 increases as the doping time (plasma process time) increases. Thus, as the doping time (plasma process time), which is a time interval from a time when introduction of boron into the semiconductor substrate 3 is begun to a time when introduction of boron into the semiconductor substrate 3 is ended, is increased, the dosage of boron introduced into the semiconductor substrate 3 increases.

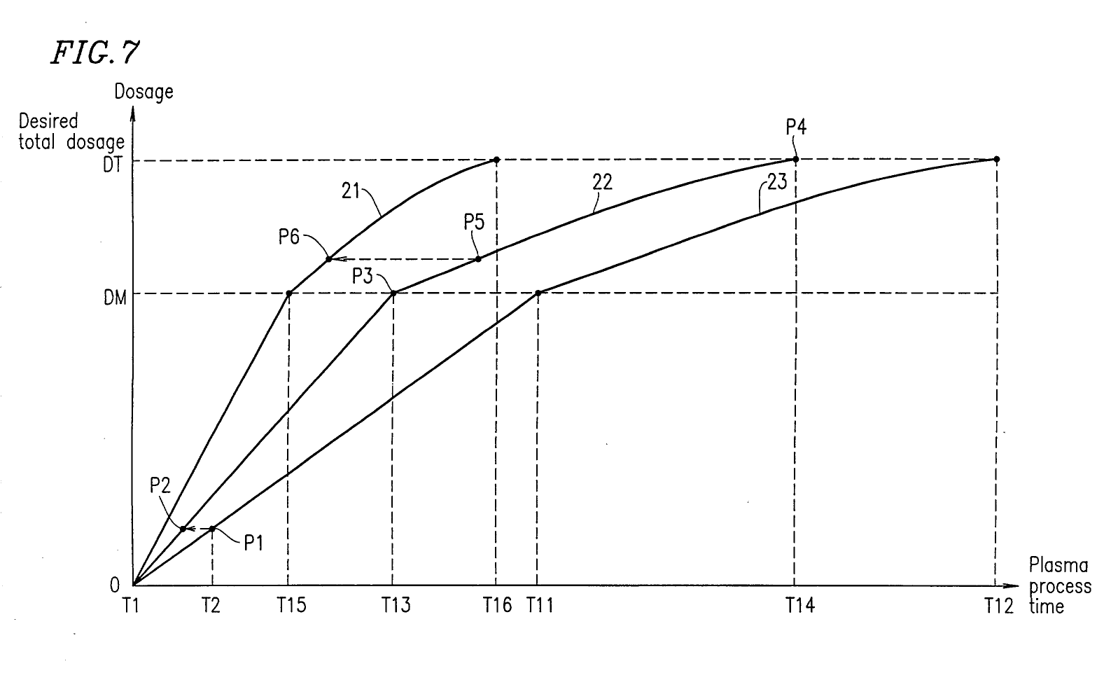

FIG. 7 is a graph showing the relationship between the dosage of boron, which represents the quantity of boron introduced into the semiconductor substrate 3 of the present embodiment and the plasma process time, for respective emission intensities of BH radicals. The horizontal axis represents the plasma process time, which is a time interval from a time when introduction of boron into the semiconductor substrate 3 is begun to a time when introduction of boron into the semiconductor substrate 3 is ended. The vertical axis represents the dosage of boron, which represents the quantity of boron introduced into the semiconductor substrate 3.

The emission intensity of BH radicals on a curve 21 is larger than that on a curve 22. The emission intensity of BH radicals on the curve 22 is larger than that on a curve 23. In FIG. 7, for simplicity of illustration, the three curves 21, 22, and 23 are provided for three levels of emission intensities of BH radicals in the form of graphs. However, more than three curves actually exist according to continuously changing emission intensities of BH radicals.

As described above, as the plasma process time is increased, the dosage of boron increases. As shown in FIG. 7, the increase rate of the dosage varies according to the emission intensity of BH radicals, which represents the state of plasma used for converting B₂H₆ included in the source gas into the form of plasma. At certain emission intensity of BH radicals, the dosage of boron introduced into the semiconductor substrate 3 changes as shown in the curve 21 with the passage of the plasma process time. After introduction of boron into the semiconductor substrate 3 begins at time T1, the dosage of boron increases until time T15 at a predetermined rate so as to reach dosage DM. After the dosage exceeds dosage DM, the rate of increase of the dosage with respect to the plasma process time is decreased, and desired total dosage DT is reached at time T16.

For another emission intensity of BH radical, the dosage of boron changes as shown in curve 22 with the passage of the plasma process time. After introduction of boron into the semiconductor substrate 3 begins at time T1, the dosage of boron increases at a lower rate of increase than that for curve 21, and dosage DM is reached at time T13, later than time T15 at which dosage DM is reached in curve 21. For curve 22, after the dosage exceeds dosage DM, the rate of increase of the dosage with the passage of the plasma process time decreases similarly to curve 21, and desired total dosage DT is reached at time T14, later than time T16 at which dosage DT is reached in curve 21.

For still another emission intensity of BH radicals, the dosage of boron changes as shown in the curve 23. After introduction of boron into the semiconductor substrate 3 begins at time T1, the dosage of boron increases at a lower rate of increase than that for the curve 22, and dosage DM is reached at time T11, later than time T13 at which dosage DM is reached in curve 22. For curve 23, after the dosage exceeds dosage DM, the increase rate of the dosage with the passage of the plasma process time decreases similarly to curves 21 and 22, and desired dosage DT is reached at time T12, later than time T14 at which dosage DT is reached in curve 22.

Thus, the relationship between the dosage of boron and the plasma process time varies according to the emission intensity of BH radicals. The plasma process time control section 9 includes a storage section (not shown). In the storage section, the relationship between the dosage of boron and the plasma process time which varies according to the emission intensity of BH radicals is previously stored.

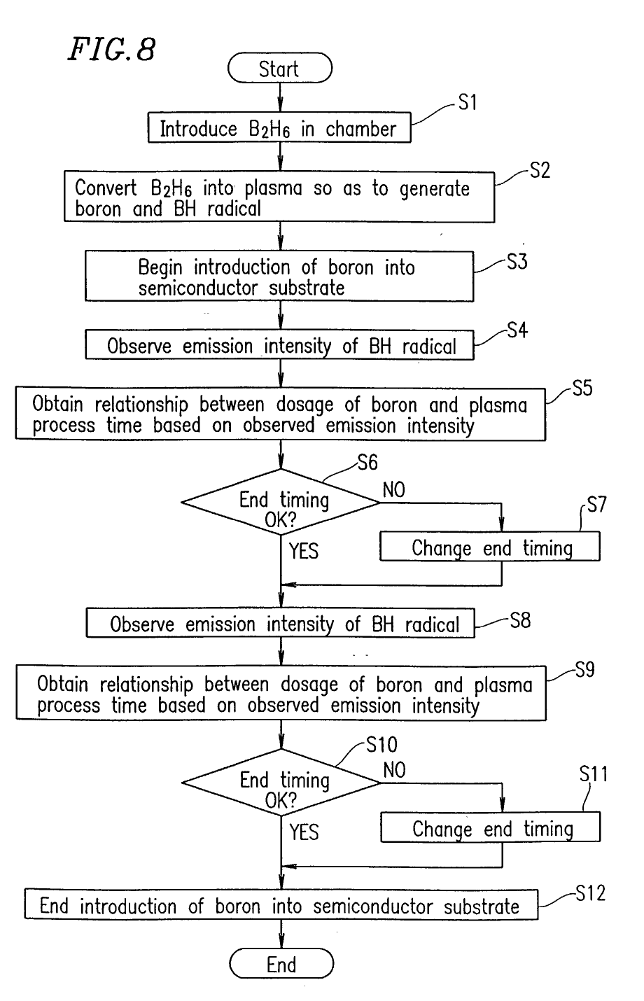

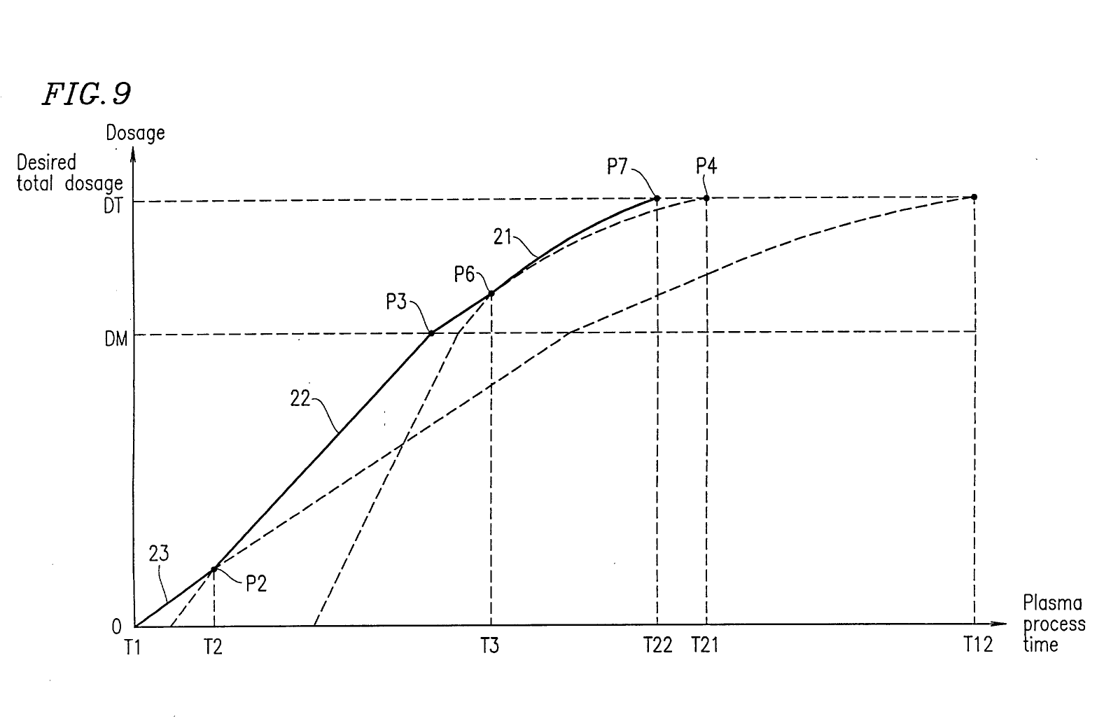

Hereinafter, an operation of the MOS transistor production apparatus 1 according to the present embodiment is described. FIG. 8 is a flowchart illustrating a procedure of a surface treatment method according to the present embodiment. FIG. 9 is a graph showing the relationship between the plasma process time and the dosage of boron in the surface treatment method of the present embodiment. Similarly to FIG. 7 described above, the horizontal axis represents the plasma process time, and the vertical axis represents the dosage of boron.

First, the semiconductor substrate 3 shown in FIG. 2, wherein the N well region 11, the gate oxide film 12, and the gate electrode 13 are formed on the P-type silicon substrate 10, is mounted on the substrate holding table 4 provided in the chamber 2. The mixer provided in the source supply section 5 mixes b₂H₆ and He, which are stored in separate containers in the form of gas, at a certain ratio. The source gas including B₂H₆ and He gases mixed therein is adjusted by a flow rate adjuster having a bulb (not shown) so as to have the flow rate of about 200 sccm, and supplied into the chamber 2 (step S1).

The ECR plasma source 6 applies about 500 watts (W) of power into the chamber 2 having the vacuum degree of about 4×10⁻⁴ Torr so as to generate plasma. When the plasma is generated by the ECR plasma source 6, B₂H₆ included in the source gas supplied into the chamber 2 is converted into plasma, so as to generate ions or radicals of boron or a boron compound, such as B⁺, B₂⁺, B₂H₂⁺, or the like; ions or radicals of hydrogen, such as H⁺, H₂⁺, or the like; and BH radicals (step S2).

Next, the RF power supply 8 starts to apply RF power of about 300 watts (W) to the semiconductor substrate 3 held by the substrate holding table 4 provided in the chamber 2. After the beginning of application of power of about 300 watts (W) by the RF power supply 8, self-bias of about 700 volts (V) occurs. When self-bias of about 700 volts (V) occurs in the semiconductor substrate 3, introduction of boron generated at step S2 is begun at time T1 shown in FIG. 9 by means of a supply of accelerated energy of about 700 electron volt (eV). The following description is based on an assumption that BH radical emits light at the emission intensity corresponding to the curve 23. Further, the time at which introduction of boron into the semiconductor substrate 3 is ended is set to time T12 according to curve 23 described above with reference to FIG. 7. Thus, the plasma process time, which represents a time interval from a time when introduction of boron in the form of plasma into the semiconductor substrate 3 is begun to a time when introduction of boron into the semiconductor substrate 3 is ended, is set to the time interval of (time T12−time T1) (step S3).

Thereafter, at time T2 shown in FIG. 9, the plasma measurement device 7 measures the intensity of emission at a wavelength of 4332 Å which corresponds to a transition of (A1Π−X1Σ) of BH radicals (step S4).

Thereafter, the plasma process time control section 9 obtains from the storage section (not shown) the relationship between the dosage of boron at the measured emission intensity and the plasma process time based on the emission intensity of BH radical measured at time T2 by the plasma measurement device 7 (step S5).

Next, the plasma process time control section 9 determines whether or not the set time to end introduction of boron into the semiconductor substrate 3 is appropriate, based on the relationship between the dosage of boron obtained at step S5 and the plasma process time (step S6). If it is determined that the time to end introduction of boron into the semiconductor substrate 3 is not appropriate (“No” at step S6), the plasma process time control section 9 changes the time to end introduction of boron into the semiconductor substrate 3 such that the total dosage of boron, which represents the total quantity of boron introduced into the semiconductor substrate 3, becomes equal to desired total dosage DT (step S7).

For example, since the state of plasma which is used for converting B₂H₆ into the form of plasma varies within the time interval from time T1 to time T2, the relationship between the dosage of boron obtained at step S5 and the plasma process time does not follow curve 23 which is a curve to be originally followed. When the relationship follows curve 22 shown in FIG. 7, the plasma process time control section 9 translates curve 22 from point P2 to point P1 of FIG. 7 along the plasma process time axis, so as to obtain the curve shown in FIG. 9. Then, the plasma process time control section 9 changes the time to end introduction of boron into the semiconductor substrate 3, from time T12 to time T21 at which the translated curve 22 reaches desired total dose DT at point P4. In this way, the plasma process time control section 9 changes the time to end introduction of boron into the semiconductor substrate 3 from time T12 to time T21 which is prior to time T12. That is, the plasma process time control section 9 controls the plasma process time based on the measurement result obtained by the plasma measurement device 7 such that the total dosage of boron becomes equal to desired total boron dosage DT.

When it is determined that the time to end introduction of boron into the semiconductor substrate 3 is appropriate (“Yes” at step S6), or when the plasma process time control section 9 changes the time to end introduction of boron into the semiconductor substrate 3 (step S7), the plasma measurement device 7 measures the intensity of emission at a wavelength of 4332 Å which corresponds to a transition of (A1Π−X1Σ) of BH radicals (step S8).

Next, the plasma process time control section 9 obtains from the storage section (not shown) the relationship between the dosage of boron at the measured emission intensity and the plasma process time based on the emission intensity of BH radicals measured at time T3 by the plasma measurement device 7 (step S9).

Next, the plasma process time control section 9 determines whether or not the time to end introduction of boron into the semiconductor substrate 3 is appropriate, based on the relationship between the dosage of boron obtained at step S9 and the plasma process time (step S10). If it is determined that the time to end introduction of boron into the semiconductor substrate 3 is not appropriate (“No” at step S10), the plasma process time control section 9 changes the time to end introduction of boron into the semiconductor substrate 3 such that the total dosage of boron, which represents the total quantity of boron introduced into the semiconductor substrate 3, becomes equal to desired total dosage DT (step S11).

For example, since the state of plasma varies after the emission intensity of BH radicals has been measured at time T2 within the time interval from time T2 to time T3, the relationship between the dosage of boron obtained at step S9 and the plasma process time does not follow curve 23 which is a curve to be originally followed, but follow curve 22. In such a case, the plasma process time control section 9 translates curve 21 from point P6 to point P5 of FIG. 7 along the horizontal axis, so as to obtain the curve shown in FIG. 9. Then, the plasma process time control section 9 further changes the time to end introduction of boron into the semiconductor substrate 3, from time T21 to time T22 at which the translated curve 21 reaches desired total dose DT at point P7. In this way, the plasma process time control section 9 further changes the time to end introduction of boron into the semiconductor substrate 3 from time T21 to time T22 which is prior to time T21.

When it is determined that the time to end introduction of boron into the semiconductor substrate 3 is appropriate (“Yes” at step S10), or when the plamsa process time control section 9 changes the time to end introduction of boron into the semiconductor substrate 3 (step S11), introduction of boron into the semiconductor substrate 3 is ended at a time when the total dosage of boron, which represents the total quantity of boron introduced into the semiconductor substrate 3, becomes equal to desired total dosage DT (step S12). For example, at time t22 changed at step S11, the RF power supply 8 ended applying the RF power to the semiconductor substrate 3, and generation of plasma by the ERC plasma source 6 is stopped, whereby introduction of boron into the semiconductor substrate 3 is ended.

As described above, according to the present embodiment, the plasma process time control section 9 obtains the relationship between the dosage of boron at the measured emission intensity and the plasma process time based on the intensity of emission at a wavelength of 4332 Å which corresponds to a transition of (A1Π−X1Σ) of BH radicals measured by the plasma measurement device 7. The plasma process time control section 9 changes the time to end introduction of boron into the semiconductor substrate 3 such that the total dosage of boron, which represents the total quantity of boron introduced into the semiconductor substrate 3, becomes equal to desired total dosage DT, based on the obtained relationship between the dosage of boron and the plasma process time.

Thus, even if the state of plasma used for converting B₂H₆into the form of plasma varies, the total dosage of boron, which represents the total quantity of boron introduced into the semiconductor substrate 3, becomes equal to desired total dosage DT. Therefore, in a semiconductor device produced by utilizing plasma doping, variations in the electric resistance values of the source region, drain region, and gate electrode can be removed. As a result, the device driving power of the semiconductor device produced by utilizing plasma doping results in uniform power, and the yield of such a semiconductor device can be increased.

Furthermore, according to the present embodiment, the doping time (plasma process time), which has no relation to the parameters for generating plasma, is changed without changing the parameters for generating plasma. Thus, the previously described problem (it is difficult to control a variation in the state of plasma by adjusting the parameters for generating plasma because, when one of a plurality of parameters is changed, the other parameters are accordingly changed, i.e., the state of plasma does not change according to the changes in the parameters as desired) can be solved.

In the present embodiment, the surface treatment method employed in production of a MOS transistor has been described as an example, but the present invention is not limited thereto. The surface treatment method of the present invention can be employed not only for production of a semiconductor device, such as a MOS transistor or the like, but also, in various fields, for adding a specific characteristic to, or improving a specific characteristic of, a substratum by introducing a suitable element, or the like, into the substratum, so long as the surface treatment method of the present invention is used to introduce a plasma substance, which is an atom, a molecule, a compound, an alloy, or the like, in the form of plasma, into a substratum, such as a semiconductor substratum or the like.

The “specific characteristic” includes, for example, mechanical characteristics, such as abrasion resistance, lubricity, parting characteristic, anti-corrosivity, or the like; electromagnetic characteristics, such as electric conductivity, electromagnetic shielding characteristic, magnetic characteristic, or the like; optical characteristics, such as optical absorptivity, optical reflectivity, gloss characteristic, and coloring characteristic, or the like; and thermal characteristics, such as heat resistance, thermal conductivity, or the like. For example, the present, invention can be applied to a surface treatment method wherein a substance which decreases a friction coefficient is introduced to a surface of a bearing member in order to reduce the friction coefficient of the bearing member.

In the present embodiment, an example where the emission intensity of BH radicals generated at step S2 is measured after time T1 at which introduction of boron into the semiconductor substrate 3 is begun, has been described, but the present invention is not limited thereto. The emission intensity of BH radicals generated at step S2 prior to time T1 may be measured so as to obtain the relationship between the dosage of boron at the measured emission intensity of BH radicals and the plasma process time; and the times to begin and end introduction of boron into the semiconductor substrate 3 may be set based on the obtained relationship between the dosage of boron and the plasma process time.

In the present embodiment, a mixture of B₂H₆ and He in the form of gas is supplied into the chamber 2, but the present invention is not limited thereto. B₂H₆ and He in the form of liquid may be supplied into the chamber 2, and may then be evaporated in the chamber 2.

Furthermore, the ECR plasma source is used as a plasma source in the above example, but an ICP-type plasma source or a parallel-plate plasma source may be used.

In the above example, observation of BH radicals is realized by emission spectrometry where the emission intensity of BH radicals is measured. However, ions or radicals of boron or a boron compound may be observed. Alternatively, ions or radicals of boron or a boron compound may be observed using any of laser-induced fluorescence spectroscopy, an E×B filter, and quadrupole mass spectrometry (QMAS) in place of emission spectrometry.

In the above example, the plasma measurement device 7 is provided outside the chamber 2. However, the plasma measurement device 7 may be provided inside the chamber 2.

In the above example, the number of times the plasma measurement device 7 measures the emission intensity of BH radical is two times. However, the number of times the plasma measurement device 7 measures the emission intensity may be one time, or may be three times or more.

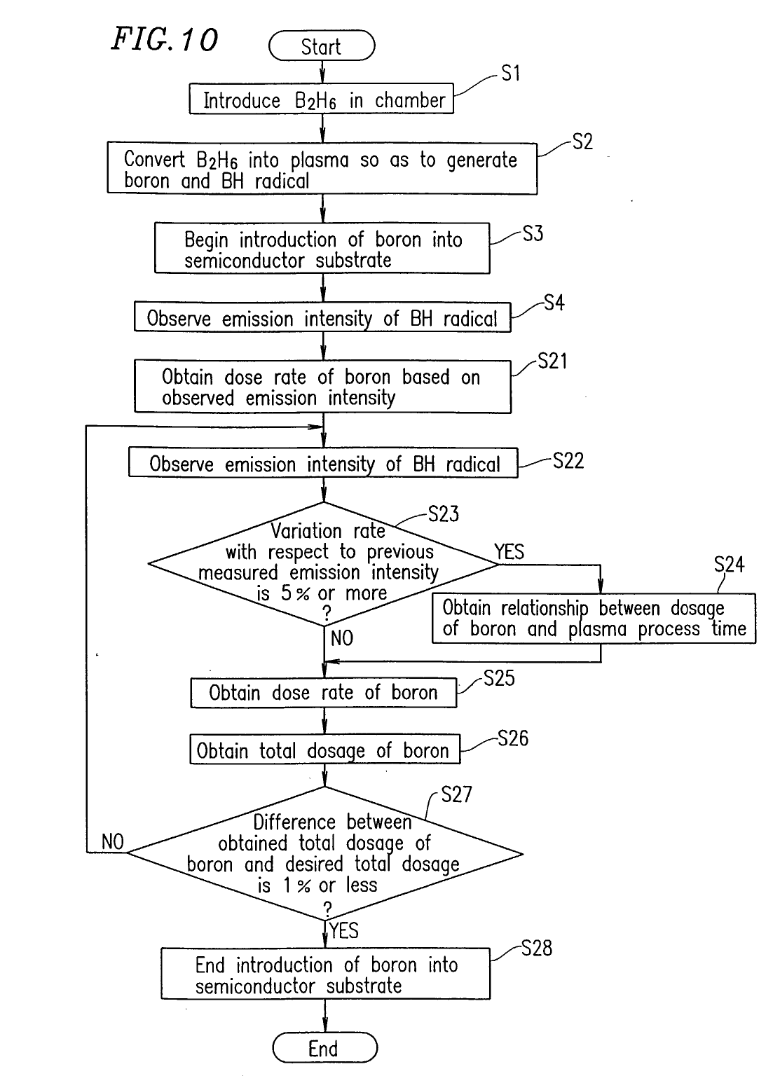

FIG. 10 is a flowchart illustrating a procedure of another surface treatment method according to the present embodiment. In FIG. 10, like elements are indicated by like reference numerals used in the flowchart of FIG. 8 which illustrates the procedure of the surface treatment method of the present embodiment. Detailed descriptions of these elements are omitted.

At first, the semiconductor substrate 3 shown in FIG. 2 is mounted on the substrate holding table 4 provided in the chamber 2. Then, the source gas including B₂H₆ and He gases is supplied into the chamber 2 (step S1).

The ECR plasma source 6 generates plasma in the chamber 2. When the plasma is generated, B₂H₆ included in the source gas is converted into plasma, so as to generate ions or radicals of boron or a boron compound, such as B⁺, B₂⁺, B₂H₂⁺, or the like; ions or radicals of hydrogen, such as H⁺, H₂⁺, or the like; and BH radicals (step S2).

Next, the RF power supply 8 starts to apply RF power to the semiconductor substrate 3 held by the substrate holding table 4 provided in the chamber 2. After the beginning of the application of RF power to the semiconductor substrate 3, self-bias occurs in the semiconductor substrate 3. When self-bias occurs in the semiconductor substrate 3, introduction of boron, which is generated at step S2, into the semiconductor substrate 3 is begun (step S3).

Thereafter, the plasma measurement device 7 measures the intensity of emission at a wavelength of 4332 Å which corresponds to a transition of (A1Π−X1Σ) of BH radical (step S4).

Then, the plasma process time control section 9 reads from the storage section (not shown) the relationship between the dosage of boron at the measured emission intensity and the plasma process time based on the emission intensity of BH radicals measured at step S4, and obtains the dose rate of boron to be introduced into the semiconductor substrate 3 based on the read relationship between the dosage of boron and the plasma process time (step S21).

Then, the plasma measurement device 7 measures the intensity of emission at a wavelength of 4332 Å which corresponds to a transition of (A1Π−X1Σ) of BH radicals (step S22).

Next, the plasma process time control section 9 determines whether or not the emission intensity of BH radicals currently measured at step S22 is varied from the just previously measured emission intensity of BH radicals by 5% or more (step S23). If it is determined that the emission intensity of BH radicals currently measured at step S22 is varied from the just previously measured emission intensity of BH radical by 5% or more (“Yes” at step S23), the plasma process time control section 9 reads from the storage section (not shown) the relationship between the dosage of boron at the currently measured emission intensity and the plasma process time based on the emission intensity of BH radicals currently measured at step S22 (step S24).

When the plasma process time control section 9 reads from the storage section (not shown) the relationship between the dosage of boron at the currently measured emission intensity and the plasma process time (step S24), or it is determined that the emission intensity of BH radical currently measured at step S22 is not varied from the just previously measured emission intensity of BH radical by 5% or more (“No” at step S23), the plasma process time control section 9 obtains the dose rate of boron introduced into the semiconductor substrate 3 based on the relationship between the dosage of boron and the plasma process time, which is read at step S24 (step S25).

When a variation in the emission intensity of BH radicals currently measured at step S22 with respect to the just previously measured emission intensity of BH radicals is smaller than 5%, step S24 of reading from the storage section (not shown) the relationship between the dose of boron and the plasma process time is omitted, and the dose rate of boron introduced into the semiconductor substrate 3 is obtained using the relationship between the dose of boron and the plasma process time just previously read from the storage section.

Next, the plasma process time control section 9 obtains the total dosage of boron, which represents the total quantity of boron introduced into the semiconductor substrate 3, based on the dose rate of boron which is obtained every time the emission intensity of BH radical is measured (step S26).

Thereafter, the plasma process time control section 9 determines whether or not the difference between the total dosage of boron obtained at step S26 and a predetermined desired total dosage is equal to or smaller than 1% (step S27). If it is determined that the difference between the total dosage of boron obtained at step S26 and a predetermined desired total dosage is not yet equal to or smaller than 1% (“No” at step S27), the process returns to step S22, and observation of the emission intensity of BH radicals is repeated. If it is determined that the difference between the total dosage of boron obtained at step S26 and a predetermined desired total dosage is equal to or smaller than 1% (“Yes” at step S27), introduction of boron into the semiconductor substrate 3 in ended (step S28).

In the present embodiment, the semiconductor substrate is formed of silicon (Si), but the present invention is not limited thereto. The semiconductor substrate may be formed of Si—C, Ge, Si—Ge, Si—Ge—C, GaAs, InP, ZnSe, CdFe, or InSb. Further, in the above example, boron (B) is used as the impurity. However, as the impurity, N, P, As, Sb, Bi, Al, Ga, In, Tl, C, Si, Ge, Sn, Pb, O, S, Se, Te, F, Cl, Br, I, Cu, Ag, or Au may be used. Furthermore, in the above example, the emission intensity of BH radical is observed at the observation step,. However, in place of the emission intensity of BH radical, the emission intensity of ions or radicals of an atom, molecule, or compound of each of the above elements, which may be used as the impurity, may be observed.

### Industrail Applicability

According to the present invention, as described above, there is provided a surface treatment method and production method of a semiconductor device which achieves reduction of the production time.

Furthermore, according to the present invention, there is provided a surface treatment method and production method of a semiconductor device which achieves improvement of yield.

1. A surface treatment method, comprising:
a plasma conversion step of using plasma to convert a substance into the form of plasma, thereby generating a first plasma substance and a second plasma substance;
a step of beginning introduction of the first plasma substance, which is generated by using the plasma, into a substratum;
a step of ending introduction of the first plasma substance into the substratum;
a step of observing the state of the second plasma substance, which is generated by using the plasma, prior to the ending step; and
a step of controlling a plasma process time, which represents a time interval from the beginning step to the ending step, based on the observation result obtained at the observation step, such that a total dosage of the first plasma substance, which represents a total quantity of the first plasma substance introduced into the substratum, becomes equal to a desired total dosage.

2. A surface treatment method according to claim 1, wherein:
the observation step is performed after the beginning step;
the observation step observes an emission intensity of the second plasma substance generated by using the plasma; and
the controlling step obtains, based on the emission intensity observed at the observation step, a relationship between the plasma process time and a dosage of the first plasma substance, which represents a quantity of the first plasma substance introduced into the substratum, and controls a timing at which the ending step is performed according to the relationship between the plasma processing time and the dosage of the first plasma substance.

3. A surface treatment method according to claim 1, wherein: the observation step is performed prior to the beginning step.

4. A surface treatment method according to claim 1, wherein:
the second plasma substance generated at the plasma conversion step contains ions or radicals; and
the observation step observes the state of one of the ion and the radical using one of emission spectrometry and laser-induced fluorescence spectroscopy.

5. A surface treatment method according to claim 1, wherein:
the second plasma substance generated at the plasma conversion step contains ions; and
the observation step observes the state of the ions using one of an E×B filter and quadrupole mass spectrometry (QMAS).

6. A surface treatment method according to claim 1, wherein:
the plasma conversion step converts the substance into the form of plasma in a chamber, thereby generating the first plasma substance and the second plasma substance; and
the observation step observes the state of the second plasma substance from outside of the chamber.

7. A surface treatment method according to claim 1, wherein:
the plasma conversion step converts the substance into the form of plasma in a chamber, thereby generating the first plasma substance and the second plasma substance; and
the observation step observes the state of the second plasma substance from inside the chamber.

8. A surface treatment method according to claim 1, wherein:
the substratum is a semiconductor substrate; and
the substance is an impurity.

9. A surface treatment method according to claim 1, wherein the first plasma substance is boron.

10. A surface treatment method according to claim 1, wherein the second plasma substance contains BH radicals.

11. A production apparatus of a semiconductor device, comprising:
holding means for holding a semiconductor substrate in a chamber;
source gas supply means for supplying a source gas including an impurity into the chamber;
a plasma source for generating plasma used for converting the impurity, which is included in the source gas supplied by the source gas supply means, into the form of plasma, thereby generating a first plasma impurity and a second plasma impurity in the chamber;
introduction means for introducing the first plasma impurity into the semiconductor substrate;
observation means for observing the state of the second plasma impurity which is generated using the plasma;
control means for controlling a plasma process time, which represents a time interval from a time when introduction of the first plasma impurity into the semiconductor substrate is begun to a time when introduction of the first plasma impurity into the semiconductor substrate is ended, based on the observation result obtained by the observation means, such that a total dosage of the first plasma impurity, which represents a total quantity of the first plasma impurity introduced into the semiconductor substrate, becomes equal to a desired total dosage.

12. A surface treatment method, comprising:
a plasma conversion step of using plasma to convert a substance into the form of plasma, thereby generating a first plasma substance and a second plasma substance;
a step of beginning introduction of the first plasma substance, which is generated by using the plasma, into a substratum;
a step of observing the state of the second plasma substance which is generated by using the plasma;
a step of obtaining a dose rate of the first plasma substance introduced into the substratum, based on the observation result at the observation step,
a step of obtaining a total dosage of the first plasma substance, which represents the total quantity of the first plasma substance introduced into the substratum, based on the dose rate obtained at the dose rate obtaining step; and
a step of ending introduction of the first plasma substance into the substratum, based on the total dosage obtained at the total dosage obtaining step and a predetermined desired total dosage.
